(19) United States
(12) Patent Application Publication
(10) Pub. No.: US 2024/0021600 A1
(43) Pub. Date: Jan. 18, 2024

(54) SEMICONDUCTOR DEVICES AND METHODS OF MANUFACTURING THEREOF

(71) Applicant: Taiwan Semicondutor Manufacturing Company, Ltd., Hsinchu (TW)

(72) Inventors: Po-Hsien Yen, New Taipei City (TW); Jia-Hong Gao, Hsinchu (TW); Hui-Zhong Zhuang, Hsinchu (TW); Jung-Chan Yang, Longtan Township (TW)

(73) Assignee: Taiwan Semicondutor Manufacturing Company, Ltd., Hsinchu (TW)

(21) Appl. No.: 17/863,139

(22) Filed: Jul. 12, 2022

(51) Int. Cl. H01L 27/02; G06F 30/392; G06F 30/31

(52) U.S. Cl. CPC H01L 27/0207; G06F 30/392; G06F 30/31

(57) ABSTRACT

Systems and methods for an integrated circuit layout is disclosed. The integrated circuit layout includes a first block including multiple first cells, each of which has a first cell height, and a second block including multiple second cells, each of which has a second cell height. The first block is disposed next to the second block with a spacing that is either equal to zero or less than any of the first or second cell heights.

### BACKGROUND

Generally, electronic design automation (EDA) tools assist semiconductor designers to take a behavioral description of a desired circuit and work to fashion a finished layout of the circuit ready to be manufactured. This process usually takes the behavioral description of the circuit and turns it into a functional description, which is then decomposed into a number of Boolean functions and mapped into respective cell rows using a standard cell library. In some cases, more than one cell may be available to perform a given function, according to a desired density, performance, etc. The standard cells may be the intellectual property of a designer, or associated with the EDA tools, and may be termed as intellectual property blocks (IP blocks) or functional blocks.

The cell rows containing the IP blocks are mapped to a geographic area of a semiconductor device, such as a silicon wafer (which may be subdivided into a plurality of semiconductor chips). The placement of the IP blocks may affect a final performance of the device. For example, placing various high power IP blocks in close proximity may lead to a local hotspot on the semiconductor chips during operation. Additionally, various placements may impact routing of various power, and clock signals, and thus may thereby affect the manufacturability or performance of a semiconductor device. Although sophisticated strategies are used to determine the placement and selection of various IP blocks, further advancements in the state of the art are needed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a schematic diagram of a cell of an example integrated circuit layout, in accordance with some embodiments.

FIG. 1B illustrates a schematic diagram of another cell of an example integrated circuit layout, in accordance with some embodiments.

FIG. 2 illustrates a schematic diagram of blocks of cells of an example integrated circuit layout, in accordance with some embodiments.

FIG. 3A illustrates of schematic diagram of a dummy cell of an integrated circuit layout, in accordance with some embodiments.

FIG. 3B illustrates a schematic diagram of another dummy cell of an integrated circuit layout, in accordance with some embodiments.

FIG. 4 illustrates another schematic diagram of blocks of cells of an example integrated circuit layout, in accordance with some embodiments.

FIG. 5A illustrates an abutting pair of same-type cells, in accordance with some embodiments.

FIG. 5B illustrates a non-abutting pair of same-type cells, in accordance with some embodiments.

FIG. 6A illustrates an abutting pair of different-type cells, in accordance with some embodiments.

FIG. 6B illustrates a non-abutting pair of different-type cells, in accordance with some embodiments.

FIG. 7A is an example flow chart of a method for fabricating a semiconductor device, in accordance with some embodiments.

FIG. 7B is another example flow chart of a method for fabricating a semiconductor device, in accordance with some embodiments.

FIG. 8 is yet another example flow chart of a method for fabricating a semiconductor device, in accordance with some embodiments.

FIG. 9 illustrates a block diagram of an example information handling system (IHS), in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In general, a semiconductor device can be constructed from a standard cell library. The standard cell library can include cells of varying height. For example, components of varying density, drive strength, and function are included. Some dissimilar cells (e.g., cells of different height) may have design rules that are incompatible with a desired density. For example, some dissimilar cells have differing routing or placement requirements for supply voltages such as VDD and VSS. As a result, some dissimilar cells can require a substantial spacing therebetween, according to a design rule, and thus a design rule check (DRC) can flag an issue in the absence of such a spacing. A standard cell library comprising cells of varying height, having common edge cells may permit the dissimilar cells to abut one another, which may increase a density of a semiconductor device. Moreover, a spacer (i.e., dummy) cell can be introduced to a row to align the edges of IP blocks between a plurality of rows, to cause the plurality of rows to abut a common feature such as a boundary of a semiconductor die or another IP block.

An integrated circuit layout includes a plurality of cell types. For example, some cell types can be specific to a function, such as certain memory blocks. Other cell types are intended for general purpose logic. For example, cell types can include an n-well or p-well zones or areas, and various connections can be formed between the wells within or between cells to form various transistors, diodes, flip-flops, multiplexors, processors, etc. The cells may be arranged into rows and columns, to modularize designs, simplify design verification, etc. These rows and columns may have one or more common boundaries. For example an edge of a semiconductor die, or an edge of an IP block such as a processor core or a memory block may be a boundary for adjacent cells. The boundaries may be physical, such as an isolation trench, or logical, such as an edge of an IP block which is segregated from an adjoining block to speed verification, modularity, or reuse of one or both of the blocks.

The various cells may be selected from a cell library. A cell library is a plurality of cells accessible to a computing system for placement within one or more integrated circuits. A cell library can contain sub-libraries. For example, the cell library can include cells of different standardized sizes (e.g., width or height). The sizes can be integer multiples of a track width, which may relate to a minimum feature size (e.g., based on a mask limit, a routing requirement, or a design decision). For example, a cell library may contain 7 track, 10 track, and 12 track libraries. For example, the track can refer the thickness of a metallization layer. The thickness may include the thickness of a physical track, such as for routing, additional space needed for manufacturing (e.g., for manufacturing tolerances, additional processes, etc.), and a distance needed to avoid interference between the tracks. The standardization of size of tracks may allow IP blocks of various vendors or types to be included in a semiconductor device.

Each cell can connect to one or more signals such as data, clocks and power. For example, each cell may comprise a pair of edge cells (e.g., disposed along a top and bottom edge) to receive a supply voltage including one or more power rails VDD, and one or more ground rails VSS. A junction of two abutting cells can be shared. For example, a VDD or VSS rail may be shared between two abutting cells. For example, a first and second abutted cell may both have a 15.5 unit edge cell, and a 31 unit power rail can be passed along the junction thereof. According to various cell libraries, edge cells may be a portion of a cell, which, advantageously, may include the edge cell connections in various cells of the library. In some embodiments, the edge cells may be a distinct cell which is appended to an edge of a cell, or aligned along an edge of a cell without a defined edge cell in the cell library.

Units can vary according to a cell library. For example, each unit can correspond to a nanometer, or a portion thereof. The embodiments depicted herein are not intended to limit the disclosure based on a particular dimension of a cell. For example, a unit may also refer to an angstrom or a micrometer, or fractional unit thereof. The harmonization of various dimensions in the cell library may simplify the placement of various cells. For example, a cell library having a single width may result in simplified placement relative to a cell library having a plurality of widths. Conversely a library having a plurality of widths may include additional cell types or optimize an available die area. The systems and methods described herein can be applied to the widths of cells as to the height of cells (e.g., to interface between the various rows described herein).

The height of the edge cells may vary based on a cell type. Some sets of cells have power requirements approximately proportional to an edge height, and may thus contain edge cells proportional to an overall cell height. For example, some of the 7T, 10T, and 12T cells can have an edge cells that is about 20% of the total cell height. Some cells may require a greater or lesser portion of the cell for the edge cells. Further, a first and second IP vendor may design cells of a same height, or a height having a similar factor (e.g., a 10 unit track may be used by a first vendor having a 6T, 60 unit tall cell, and a second vendor, having a 9T, 90 unit tall cell).

Two cell types having differently sized edge cells may or may not be compatible for abutment. For example, if a first cell has a requirement of a 20 unit power rail, and a 10 unit edge cell, and a second cell has a requirement of a 10 unit power rail, and a 5 unit edge cell, the abutment of the two cells can result in insufficient power for the first cell. Moreover, other barriers to the two cells may be present. For example, a first cell type and second cell type may have incompatible routing requirements, incompatible dielectric layers, etc. The design of the second cell can be adjusted to have an edge cell of 10 units, which may render the cell abut-able to the second cell, as well as to other cells of the same type. For example, all of the second cells may be so altered, which may, advantageously increase abut-ability and simplify cell placement.

Alternatively, a portion of the second cells may not increase the size of their edge cells. Advantageously, such cells may retain a greater portion thereof for an active region for an oxide depletion area, fins, gates, etc., which may improve performance or density relative to cells having less space available for an active region. For example, the first cell may reduce the size of their respective edge cells, to be compatible with additional first cells, or with second cells. In some embodiments, the power requirement of the first cell can be based on a cell dimension (e.g., based on a maximum power used by a cell having a dimension of the first cell). One or more cells having a dimension of the first cell can adopt a reduced power rail dimension, or include the power rail, or a portion thereof, as an additional zone within the active region of the cell. Thus, the power capacity can be maintained or reduced, and cells having reduce power capacity can be lower power cells, placed proximate to a terminal of a power delivery network, or otherwise be compatibles with the reduced edge cell dimension.

A row, can include a one or more cells (i.e., a block) which are, collectively, less than the height of the row. For example, a 1000 unit tall row may contain a cell or a plurality of cells having a total height of 950 units. A design rule may require that the row be fully described by cells (e.g., because a cell description may include a description of the surface of a semiconductor die and additional layers disposed thereupon). One or more dummy cells may thus be placed to complete the cell height (e.g., between two cells or between a cell and a boundary). The dummy cells can be or comprise common cell edges which may enable one or more dummy cells to abut one or more non-dummy cells (e.g., non-dummy cells having common or non-common edge cells).

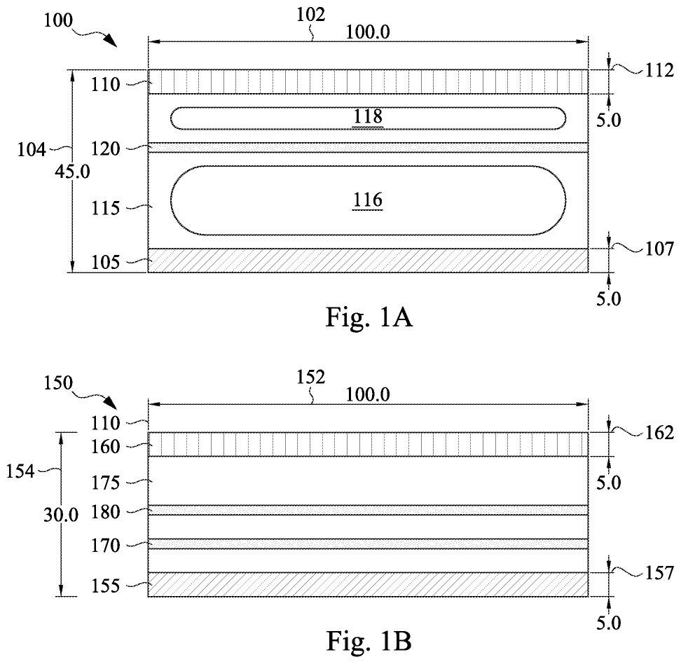

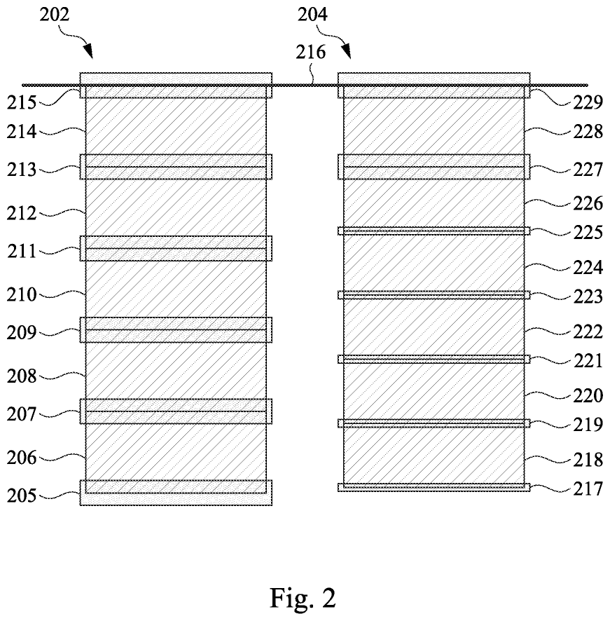

FIG. 1A illustrates a schematic diagram of a cell of an example integrated circuit layout, in accordance with some embodiments. Not all of the illustrated components are required, however, and some embodiments of the present disclosure may include additional components not shown in FIG. 1A. Variations in the arrangement and type of the components may be made without departing from the scope of the present disclosure as set forth herein. Additional, different or fewer components may be included, in accordance with some embodiments.

Referring to FIG. 1A, a cell 100 is disclosed. The cell 100 can be a standard cell of a cell library containing a plurality of cells having various associated functions, performance, heights, densities, etc. The cell 100 has a width 102 of one hundred units. The width 102 may be shared with one or more additional cell types. For example, the width 102 may be a standard width of the cell library which may simplify placement of the plurality of cells. The cell may include various active regions, which may be intended for oxide diffusion or another process (e.g., to adjust the mobility of electrons or holes within the region). In some cells, the width 102 may refer to the dimension in which two regions (e.g., and n region and a p region) are disposed alongside each other, such that the width 102 may be associated with a number of available connections therebetween, or a channel width 102 of a single connection which may, in turn, be associated with a maximum drive strength. Such a distance may also be associated with a number of gates per cell. The cell 100 has an overall height 104 of forty-five units. The overall height 104 may be an integer number of tracks, n (e.g., may be 5, 6, 7, 8, 9, 10, 11, 12, or 13 tracks). For example, the cell 100 may be a five-track cell, where each track is 9 units tall. Generally, cells may be divisible by n, and have a height based on the number of tracks or other common factor of the height one a plurality of cells (e.g., may be p×n units tall).

The cell 100 includes a bottom edge cell 105. The bottom edge cell can be defined based on a surface feature intended for a semiconductor die. For example, the bottom edge cell may be a placement area from a pad to connect a signal from a metallization layer to a die, or a keep-out to allow for passage of a metal layer trace such as a power rail over the bottom edge cell 105. The bottom edge cell 105 can accommodate a supply voltage such as VSS. A conductive element of a metallization layer can be routed along the bottom edge cell 105. In some embodiments, an adjacent cell (not depicted) may be positioned such that the supply voltage of the bottom edge cell also passes over an adjacent edge cell of the adjacent cell (which may also be termed as a bottom edge, for convenience based on the library, which may adopt a convention based on the position of the supply voltage, or as a top edge based on the placement on a semiconductor device).

The bottom edge cell 105 has an associated bottom edge cell height 107, such as one track, one half of a track, or another height (e.g., two tracks or a fractional value). Along an opposite edge of the cell, a top edge cell 110 is depicted, which may also accommodate a supply voltage (e.g., VDD). The top edge cell 110 may be symmetric to the bottom edge cell (e.g., to carry equal VDD and VS S currents). A bottom edge cell height 107 of the bottom edge cell 105 and a top edge cell height 112 of the top edge cell 110 may be based on a power of the cell 100, which may be proportional to the cell 100 area. For example, about ten percent of an area of a cell 100 may be dedicated to a bottom edge cell 105, and about ten percent may be dedicated to a top edge cell 110. The portion of a cell 100 dedicated to a top edge cell 110 or bottom edge cell 105 may vary according to a cell 100 type or purpose. For example, cells 100 may be optimized for performance (e.g., f-max), density, or power use, and may thus seek to minimize capacitance between conductive components by increasing a distance therebetween, increase a dimension (i.e., a cross sectional area) of the conductive components to lower resistance, or decrease either of a dimension or distance therebetween. Thus some cell 100 types may apportion a larger or smaller portion of the cell for the bottom edge cell 105 and the top edge cell 110.

The depicted cell also includes an 115 active region delimiting a doped region for a semiconductor device such as a such as an doped polysilicon, a dielectric, an electrically or thermally conductive portion, etc. In some embodiments, the active region may include one or more oxide diffusion regions (e.g., planar regions, fins, etc.). The oxide diffusion regions may include a p-well 116 and an n-well 118, which may, in combination, form various diodes or transistors, which may, in turn, form larger devices such as multiplexors, flip-flops, processors, and the like (e.g., within a single cell 100 or by a combination of cells 100).

The depicted cell 100 includes an additional cell zone 120. The cell zone may relate to a surface of the semiconductor device, or may relate to one or more metallization layers associated with the semiconductor device. For example, the additional cell zone 120 may be an additional supply voltage pad for connection to the active region 115, or may carry another signal such as a data or clock line to the active region. In some embodiments, the additional cell zone 120 may be a generic keep-out area, and a routing tool may populate the additional cell zone 120 according to the routing of a particular circuit, or may leave the additional cell zone 120 unpopulated. The additional cell zone 120 may also be a keep-out relative to the OD of the cell. For example, the additional cell zone 120 may be disposed between the n-well 118 and the p-well 116, such that the placement of a metal layer to chip connection may violate a design rule if placed in the additional cell zone 120. Alternatively or in addition, the additional cell zone 120 can accommodate placement of selected components such as pads (e.g., may be a keep-out for non-selected components) such as gates, fins, etc.

The additional cell zone 120 can include a supplementary supply rail. For example, a cell can include asymmetric top and bottom cells (e.g., to interface with a first adjacent cell having a first edge cell height and a second adjacent cell having a second edge cell height), and the additional zone may supplement the smaller of the two voltage rails (e.g., by passing additional current to the cell, or passing additional current through the cell as a portion of a PDN powering additional cells of a semiconductor device).

These examples are not intended to be limiting. For example, in some embodiments, the overall height of a cell may be associated with a length along which two active regions are disposed alongside each other. In some embodiments, cell libraries contain cells of various widths (i.e., wider or narrower). For example, various components (e.g., antennas, power delivery transistors, and inductors) can exceed a standard width. The width 102 may be based on or may be associated with of an associated track width, for a metallization layer including supply voltages, clock trees or other signals.

FIG. 1B illustrates a schematic diagram of another cell 150 of an example integrated circuit layout, in accordance with some embodiments. The cell 150 is contained in the same cell library as the cell 100 of FIG. 1. For example, various cells may have various widths 152 and overall heights 154. The depicted cell has a width 152 of one-hundred units (i.e., a shared width with another cell such as the cell 100 of FIG. 1A). The cell 150 has an overall height 154 of thirty-six units (i.e., a height which is not shared with at least one other cell such as the cell 100 of FIG. 1A).

The cell 150 includes a bottom edge cell 155 having a bottom edge cell height 157 equal to another cell of the cell library. For example, the depicted cell 150 has a height 157 equal to the height 107 of the bottom edge cell 105 of the cell 100 of FIG. 1A. The cell 150 also includes a top edge cell 160 having a similar top edge cell height 162 as the cell 100 of FIG. 1A. One or more of the edge cells of the second cell 150 can be a common edge cell to abut to the one or more edge cells of the cell 100 of FIG. 1A. For example, the sizing of the cell 150 may permit a ten unit power rail to pass along the boundary of the cell when abutted. The cells can also contain design rules concerning associated metal and dielectric layers to abut the cells.

Disposed between the bottom edge cell 155 and the top edge cell 160 is an active region 175. The active region 175 can contain an OD area, and receive gates coupled thereto. The active regions 175 can contain additional zones. For example, a first additional zone 170 and a second additional zone 180 can supply additional signals such as additional power or logic signals, or define additional attributes of the cell such as well boundaries.

The cell library can include further cells not specifically depicted herein. For example, the cell library can contain a cell having a similar height of the cell 150 of FIG. 1B, and a similar ratio between an overall cell height and at least one of the cell heights of the bottom edge cell 105 or top edge cell 110 of the cell 100 of FIG. 1. (e.g., may have an overall cell height of about 36 units, and a bottom and top cell height of about 3.5 units, and an active region of about 31 units). Such a cell may thus be of similar overall dimension as the cell 150 of FIG. 1B, and may contain a larger active region than the cell 150 of FIG. 1B, but may, if abutted to an instance of the cell depicted in of FIG. 1, reduce a combined dimension of the (e.g., to 7.5, rather than 10) which may result in increased capacitance, reduced dimension of a supply voltage, violation of a DRC, etc. The top edge cell and bottom edge cell may be of dissimilar size. For example, one cell of the cell library can include a thirty-six unit cell having a top edge cell of 3.5 units and a lower edge cell of five units.

The cells of the cell library may be further defined with regard to gates, connections, fins, etc. For example, the various connections, and gates which may be comprised within a cell may be prepopulated in the cell library, and connection between the various cells may be accomplished by selecting one of the prepopulated cells having the desired connections therein. Thus, the cells depicted in FIGS. 1A and 1B may be a genus comprising many species of cells, wherein each species contains various connections (e.g., between the OD regions, the power rails, and the additional zones).

FIG. 2 illustrates a schematic diagram of blocks of cells of an example integrated circuit layout, in accordance with some embodiments. A first block 202 and a second block 204 are depicted, each being comprised of a plurality of cells. The depicted cells may be disposed alongside each other, or may be disposed along different areas which abut a shared boundary 216. In some embodiments, the various zones between the cells may correspond to supply voltage rails and may be generally linear (e.g., within a semiconductor device or a region thereof). For example, the zones (or other components of the cells such as fins) may be generally horizontal, and thus may comprise additional effective boundaries.

The first block includes a first cell 206, a second cell 208, a third cell 210, a fourth cell 212, a fifth cell 214. The first cell 206 is associated with a first zone 205, which corresponds to one of a top edge cell or bottom edge cell of the first cell 206, as well as a second zone 207, which corresponds to the other of the top edge cell or bottom edge cell of the first cell 206, as well as a top edge cell or bottom edge cell of the second cell 208. For example, the cells of the first block 202 may correspond to the cell of FIG. 1A, wherein each of the top edge cells and bottom edge cells are of equal height (i.e., 5 units), and the zones 205, 207, 209, 211, and 213 adjoining the cells 206, 208, 210, 212, and 214 of the first block 202 may be about twice the height thereof (i.e., 10 units).

A sixth zone 215 corresponds, in part, to the one of the top or bottom edge cells of the fifth cell 214, and in part to a boundary 216. The boundary 216 may be, for example, an additional IP block, or an edge of a semiconductor device, and may include a corresponding edge cell associated with the sixth zone 215.

The second block 204 contains a sixth cell 218, a seventh cell 220, an eighth cell 222, a ninth cell 224, and a tenth cell 226 which are of similar overall dimension. For example, these cells 218, 220, 222, 224, and 226 may be of an overall dimension corresponding to the cell of FIG. 1B. The second block also includes a eleventh cell 228 which is of differing overall dimension to the other cells of the second block 204, and may correspond to the overall dimensions to the cell of FIG. 1A.

The sixth cell 218 is associated with a seventh zone 217, which corresponds to one of a top edge cell or bottom edge cell of the sixth cell 218, as well as an eighth zone 219, which corresponds to the other of the top edge cell or bottom edge cell of the sixth cell 218, as well as a top edge cell or bottom edge cell of the seventh cell 220. A ninth zone 221, a tenth zone 223, an eleventh zone 225, and a twelfth zone 227 overlay the intersections of the remaining cells 222, 224, 226, and 228 of the second block 204. A thirteenth zone 229 overlays the intersection of the eleventh cell 228 and the boundary 216.

The eleventh cell 228 can be the cell of FIG. 1A, having a top and bottom edge cells of 5 units, whereas each of the twelfth zone 227 and thirteenth zone 229 are 10 units wide. The tenth cell 226 can be a cell having at least one edge cell of a minimum height of 5 units abutting the eleventh cell. For example, the tenth cell, can be the cell of FIG. 1B. The sixth cell 218 through the ninth cells 224 may also be the cell of FIG. 1B, or may be another cell. For example, sixth cell 218 through the ninth cell 224 may have a larger active region and edge cells of reduced dimension. The tenth cell may be termed as a common edge cell, based on the ability of the cell to abut a cell having a relatively small edge cell such as the ninth cell 224, and a relatively large edge cell such as the eleventh cell 228. In some embodiments, the tenth cell may have similar edge cells as the sixth cell 218 through the ninth cell 224 and the eleventh cell can be a common edge cell. The eleventh cell can have asymmetric edge cells, wherein one edge cell is configured to abut another cell of similar dimension or, as depicted, a boundary, and another edge cell is configured to abut the tenth cell 226, wherein the tenth cell.

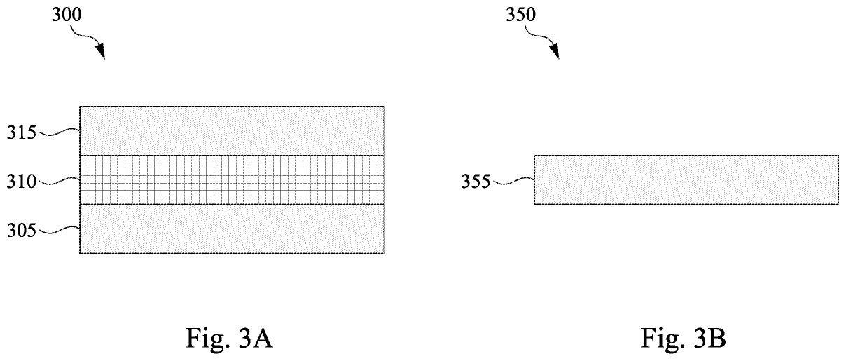

FIG. 3A depicts a first dummy cell 300 having a first region 305. The first region can contain one or more interfaces to an adjacent cell. For example, the dummy cell can include an associated metallization layer, which may ensure continuity (e.g., mechanical support, compatible dielectrics, or routing spacing) with an adjacent cell, such as another dummy cell or a non-dummy cell. The first region can be an integer multiple of an integer factor of the dummy cell 300 and another cell. For example, the dummy cell can be 65 units in height, and the first region can be 13 or 26 units in height.

The dummy cell also has a second region 310. For example, the second region of the depicted cell may be an OD area. The second region can comply with a DRC requirement and be inoperable, or can be reserved for use (e.g., may, in response to a design change, enable the alteration of a circuit of a semiconductor device by rerouting the metallization layers to include the second region as a component of a functional circuit). The active region can be or comprise an n-well, p-well, or another doped dielectric. In some embodiments, the active region can include a un-doped dielectric such as a silicon oxide. In some embodiments, the active region may be reserved region for routing, such as with a thermally or electrically conductive material. The height of the active region may be an integer of a factor of the first dummy cell 300. For example, the dummy cell can have a height of 65 units, and the active region can be 13, 26, or 39 units tall.

The dummy cell contains a third region 315 which may be similar to the first region 305. For example, the third region may be of similar composition, or of similar purpose as the first region 305. The third region may also be of similar dimension as the first region. The third region may be a height that is an integer multiple of an integer factor of the height of the cell. Continuing the previous example of a 65 unit tall cell, each of the first and third units can be 13 or 26 unit in height. Further, the first and third regions may be an integer multiple of an integer factor, such as 13 or 39 units in height. For example, each of the first and third regions may be 6.5 units or 19.5 units in height, or one of the first and third regions may be 6.5, 13, 19.5, etc. units in height and the remaining unit may be a remainder of the height.

FIG. 3B depicts a second dummy cell 350. The second dummy cell may include one or more sub-elements which may, advantageously enable the dummy cell to abut another cell. For example, if an abutting cell has a metallization spacing requirement or an active surface, the second dummy cell may inherit a requirement for spacing from the abutting cell. A requirement for a dielectric material, mechanical, electric, or thermal connection may also be inherited from an abutted cell. Indeed, such requirements may be inherited by any region of the various dummy cells depicted herein which may, advantageously, permit the dummy cells to abut various additional cells without the violation of various DRC checks.

The second dummy cell may be an integer factor of the first dummy cell. For example, the first dummy cell can be 65 units in height and the second dummy cell can be 13 units in height. In some embodiments, either of the first dummy cell, the second dummy cell, or additional cells may be limited to a maximum span (e.g., to permit necessary routing, fin passage, etc.). In some embodiments, the larger of the first dummy cell and the second dummy cell may contain additional support and thus may be associated with a larger maximum spacing. For example the first dummy cell may have a maximum span of about 130 units (about 2 cells), whereas the second dummy cell can have a maximum span of about 52 units (about 4 cells). The height of the first dummy cell can be the minimum integer multiple of the second dummy cell that violates a span constraint, or about half of the minimum integer multiple of the second dummy cell that violates the span constraint (e.g., wherein the larger dummy cell is intended to be disposed between the smaller dummy cell).

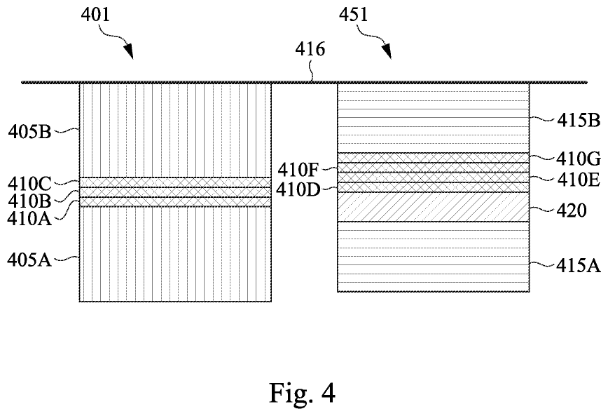

FIG. 4 depicts a first block 401 comprising first pair of cells 405 spaced by a first dummy assembly comprising a first dummy cell 410A, a second dummy cell 410B, and a third dummy cell 410C. In a non-limiting example, each of the dummy cells of the first dummy assembly are the first or second dummy cell of FIGS. 3A-3B. The first pair of cells are of a similar type, which can comprise a function, dimension, material, etc. For example, the first pair of cells 405 are of similar dimension and comprise similar oxide diffusion areas. The cells can contain connections which are identical, complementary, unrelated, etc. At least one of the pair of cells abuts a boundary 416. For example, the spacing between the first pair of cells can be defined by the abutment of an upper cell of the first pair 405B abutting the boundary, and the lower cell of the first pair 405A abutting another boundary (not depicted).

In addition to interfacing between cells, the dummy cells may also enable additional routing and alleviate thermal hot spots (e.g., by increasing thermal mass and distance between adjacent cells). The dummy cells can increase signal integrity by increasing a spacing and decreasing capacitance between various lines or decrease resistive power loss by generating a spacing which may be used to increase a dimension of a supply rail.

A second pair of cells 415 are spaced by a second dummy assembly comprising a fourth dummy cell 410D, a fifth dummy cell 410E, a sixth dummy cell 410F, a seventh dummy cell 410G, and an eight dummy cell 420. The dummy cells may be arranged to minimize a span of the cells lacking or including certain features (e.g., for manufacturability purposes). For example, the eight dummy cell may comprise one or more oxide diffusion regions or be associated with relevant routing requirements, and may be disposed above the sixth dummy cell 410F and seventh dummy cell 410G.

In some embodiments, additional cells may be present in each row. For example, the first block 401 or second block 451 may comprise several (e.g., tens, hundred, or thousands) of cells. The dummy cells may be placed throughout the block. For example, the first dummy assembly may be placed along the boundary, along a cell bounding the boundary, or elsewhere. Additional dummy assemblies may also be disposed throughout the block. The position of the additional dummy assemblies may be based on an edge cell type, a routing need, a thermal need, etc.

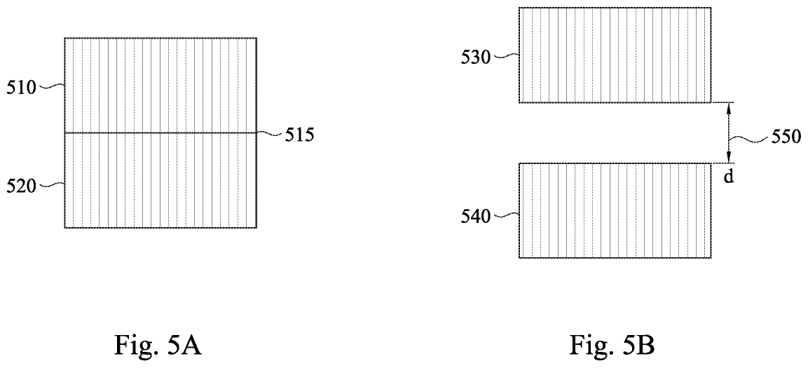

FIG. 5A depicts a first cell 510 and a second cell 520 abutted thereto. The first cell 510 and second cell 520 are of similar type. For example, the first and second cells may be of a similar overall dimension, and may comprise one or more edge cells of a similar dimension (e.g., the edge cell along the abutting edge 515). The edge cell may be a common edge cell configured for abutment to one or more cell types of a different dimension (i.e., type), or can be an edge cell intended for abutment to a similarly typed cell.

FIG. 5B depicts a first cell 530 and a second cell 540, having a gap 550 therebetween. The depicted gap 550 may be of a dimension less than the height of the first cell 530 and the second cell 540. The first cell 530 and second cell 540 can have one or more common edge cells configured for abutment to one or more cell types of a different dimension (i.e., type), or can be an edge cell intended for abutment to a similarly typed cell. For example, the common edge cells can be harmonized to abut to a plurality of cell types. One or more dummy cells can be a compatibles type, and can be placed into the gap to form a continuously defined row including the first cell 530, the one or more dummy cells (not depicted) of a height equal to the gap 550, and the second cell 540.

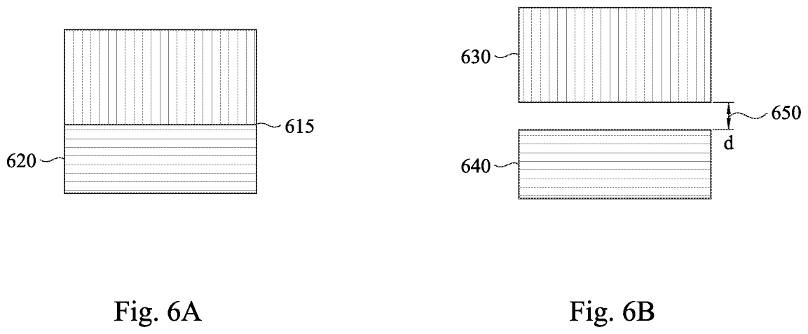

FIG. 6A depicts a first cell 610 and a second cell 620 abutted thereto. The first cell is of a first type, which may include an overall dimension of the cell. The second cell is of a second type which may include an overall dimension of the cell which is different from the first type. Each of the first cell 610 and second cell 620 may comprise a common edge cell along the abutting edge 615, such that the cells may adjoin to form a functional row (e.g., a row that does not violate DRC rules). Either of the first cell 610 or the second cell 620 may also comprise a common edge cell along an additional edge. For example, both the first cell 610 and the second cell 620 can contain a common edge cell along an upper and lower bound, which may interface with additional cells of like or unlike types, including dummy cells.

FIG. 6B depicts a first cell 630 and a second cell 640, having a gap 650 therebetween. The cells are of dissimilar type (e.g., dissimilar dimension). In some embodiments, the edge cells of the first cell 630 and second cell 640 may be configured to be directly abutted, and the gap between the cell may be to align the first cell 630, the second cell 640, or another cell of the row, or to minimize a resistance or capacitance for a circuit comprising elements of the first cell 630 or the second cell 640. In some embodiments, the edge cells of the first cell 630 and second cell 640 may be incompatible with direct abutment, and the gap may be for a dummy cell assembly which is abut-able with the first cell 630 and the second cell 640. For example, the gap may comprise a plurality of dummy cells configured to abut with the edge cells of the first cell 630 and the edge cells of the second cell 640. The dummy cells can be or comprise common edge cells.

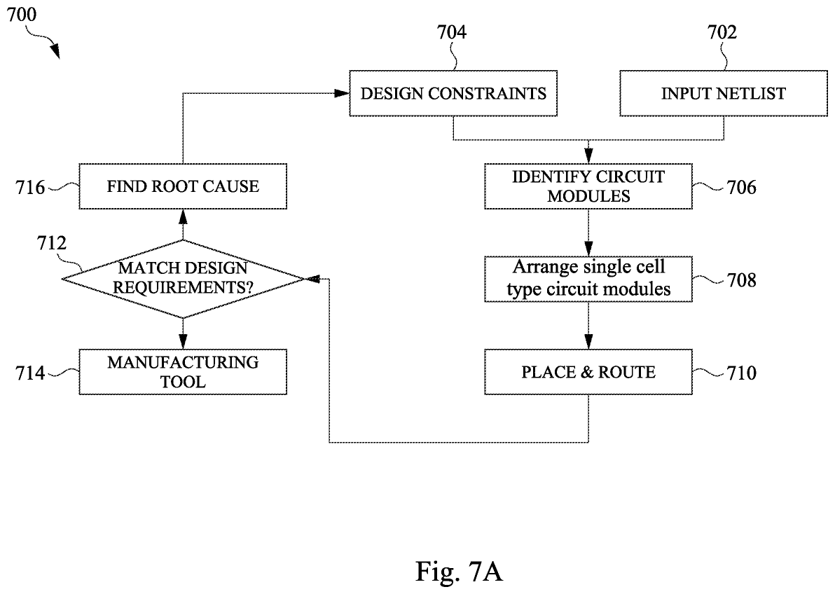

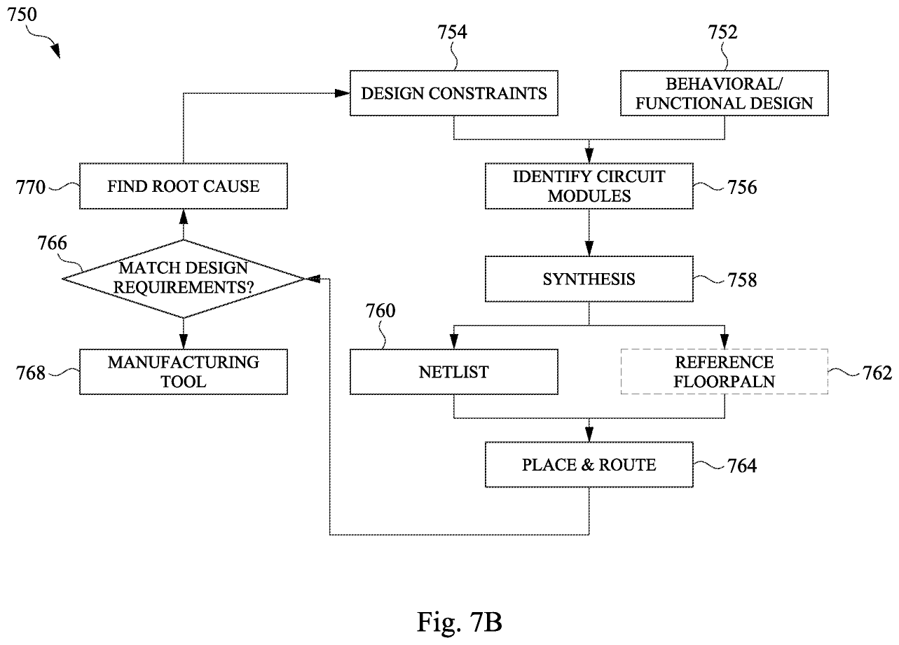

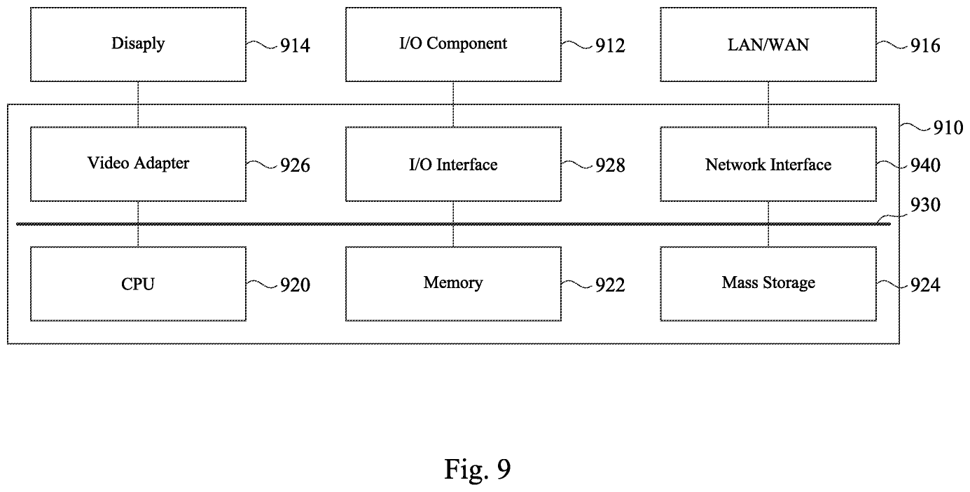

FIG. 7A illustrates a flow chart of an example method 700 of generating an integrated circuit layout including one or more common cell edges and/or one or more dummy cells, in accordance with some embodiments of the present disclosure. In some embodiments, the method 700 may be collectively referred to as an EDA. The operations of the method 700 are performed by the respective components illustrated in FIG. 9. For purposes of discussion, the following embodiment of the method 700 will be described in conjunction with FIG. 9. The illustrated embodiment of the method 700 is merely an example. Therefore, it is understood that any of a variety of operations may be omitted, re-sequenced, and/or added while remaining within the scope of the present disclosure.

At operation 702, an input netlist is provided. The input netlist may be a functionally equivalent logic gate-level circuit description provided through a synthesis process. The synthesis process forms the functionally equivalent logic gate-level circuit description by matching one or more behavior and/or functions to (standard) cells from a set of cell libraries. The behavior and/or functions are specified based upon various signals or stimuli applied to the inputs of an overall design of the integrated circuit, and may be written in a suitable language, such as a hardware description language (HDL). The input netlist may be uploaded into the processing unit 910 through the I/O interface 928 (FIG. 9), such as by a user creating the file while the EDA is executing. Alternately, the input netlist may be uploaded and/or saved on the memory 922 or mass storage device 924, or the input netlist may be uploaded through the network interface 940 from a remote user (FIG. 9). The CPU 920 can access or interface with the input netlist during execution of the EDA.

Design constraints are provided at operation 704. The design constraints constrain the overall design of a physical layout of the input netlist. In some embodiments, the design constraints may be input, for example, through the I/O interface 928, downloading through the network interface 940, or the like. The design constraints may specify timing, process parameters, and other suitable constraints with which the input netlist, once physically formed into an integrated circuit, must comply.

The method 700 identifies circuit modules at operation 706, in accordance with some embodiments. Based on the input netlist and/or the design constraints, the disclosed system can recognize, identify, or otherwise determine one or more circuit modules that are specified by the user, for example, to be constituted by the cells which may be abutted containing cells of a same type, common edge cells, dummy cells, etc. For example, the system may identify a first circuit module in response to the input netlist specifying that the first circuit module is a performance-orientated circuit module, which shall consist of tall cells. In another example, the system may identify a second circuit module in response to the input netlist specifying that the second circuit module is a power-orientated circuit module, which shall consist of the short cells. Alternately or additionally, the system can identify a circuit module by determining at least one of a timing constraint, a performance constraint, or a power constraint corresponding to the circuit module. The system can access, communicate with, or otherwise interface with the design constraints to determine such timing/performance/power constraint(s).

The method 700 proceeds to operation 708 to arrange cells in accordance with some embodiments. In response to identifying one or more circuit modules that shall consist of either the tall cells or short cells (e.g., in operation 706), the system can arrange corresponding rows of tall or short cells, or cells which are otherwise of a like type and can be abutted.

At operation 710, the cells are placed and routed, in accordance with some embodiments. In addition to selecting cells to implement the netlist, the system can place and route cells to generate a physical design for the overall integrated circuit. The operation 710 is configured to form the physical design by taking the chosen cells from cell libraries and placing them into respective cell rows. Rows containing cells which are not directly abut-able may be substituted with abut-able versions of those cell, having common edge cells, or one or more dummy cells being abut-able with the cells can be placed between the cells. Some dummy cells may be placed without a spacing or abutment requirement, such as to provide excess capacity for later routing revisions. The placement of each cell within the cell rows, and the placement of each cell row in relation to other cell rows, may be guided by cost functions in order to minimize wiring lengths and area requirements of the resulting integrated circuit. This placement may be done either automatically through the operation 710, or else may alternately be performed partly through a manual process, whereby the user may manually insert one or more cells into a cell row.

The method 700 then proceeds to operation 712 to determine whether the physical design for the overall integrated circuit matches design requirements, in accordance with some embodiments. In response to generating the actual physical design for the overall integrated circuit (in operation 710), the system can check, monitor, or otherwise determine whether the design requirements are matched by performing a series of DRC. DRC may comprise checks such as, for example, a timing quality of the actual physical design for the overall integrated circuit, a power quality of the actual physical design for the overall integrated circuit, whether a local congestion issue exists, etc., by performing one or more simulations using circuit simulators, e.g., Simulation Program with Integrated Circuit Emphasis (SPICE).

The system can perform the operation 716 to find the causes resulting in the failure of meeting the design requirements in the determination operation 712. Various causes may result in the failure. Based on the causes, the method 700 may re-perform a respective operation. For example, when the cause is due to an incorrect arrangement of cell row(s), the method 700 may proceed to an operation (e.g., the operation 704) to re-assess the constraints specified therein. When the cause is due to an infeasibility of synthesizing the functionally equivalent logic gate-level circuit description, the method 700 may proceed to an operation (e.g., the operation 704) to re-assess the constraints specified therein. When cause is due to an infeasibility of generating the actual physical design, the method 700 may proceed to an operation (e.g., the operation 710) to re-place and/or re-route.

At operation 714, the system can generate the manufacturing tool to generate, e.g., photolithographic masks, that may be used in physically manufacturing the physical design. The physical design may be sent to the manufacturing tool through the LAN/WAN 916.

FIG. 7B illustrates a flow chart of an example method 750 of generating an integrated circuit layout including one or more common cell edges and/or one or more dummy cells, in accordance with some embodiments of the present disclosure. In some embodiments, the method 750 may be collectively referred to as an EDA. The operations of the method 750 are performed by the respective components illustrated in FIG. 9. For purposes of discussion, the following embodiment of the method 750 will be described in conjunction with FIG. 9. The illustrated embodiment of the method 750 is merely an example. Therefore, it is understood that any of a variety of operations may be omitted, re-sequenced, and/or added while remaining within the scope of the present disclosure.

At operation 752, the behavioral/functional design specifies the desired behavior or function of an integrated circuit based upon various signals or stimuli applied to the inputs of an overall design of the integrated circuit, and may be written in a suitable language, such as a hardware description language (HDL). The behavioral/functional design may be uploaded into the processing unit 910 through the I/O interface 928 (FIG. 9), such as by a user creating the file while the EDA is executing. Alternately, the behavioral/functional design may be uploaded and/or saved on the memory 922 or mass storage device 924, or the behavioral/functional design may be uploaded through the network interface 940 from a remote user (FIG. 9). In these instances, the CPU 920 will access the behavioral/functional design 952 during execution of the EDA. The operation 754 of design constraints is substantially similar to the operation 704, and thus the discussion is not repeated here.

The method 750 identifies circuit modules at operation 752, in accordance with some embodiments. Based on the behavioral/functional design and/or the design constraints, the disclosed system can recognize, identify, or otherwise determine one or more circuit modules that is specified or predefined by the user, for example, to consist of either tall cells or short cells. For example, the system may identify a first circuit module in response to the behavioral/functional design specifying that the first circuit module is a performance orientated circuit module, which shall consist of tall cells. In another example, the system may identify a second circuit module in response to the behavioral/functional design specifying that the second circuit module is a power-orientated circuit module, which shall consist of short cells. Alternately or additionally, the system can identify a circuit module by determining at least one of a common timing constraint, a common performance constraint, or a common power constraint corresponding to the circuit module. The system can access, communicate with, or otherwise interface with the design constraints to determine such timing/performance/power constraint(s). In some embodiments, the system can identify, based on the behavioral/functional design, one or more circuit modules that shall not consist of only one type of the tall or short cells. The method 750 may include cells of a third type, or may include the provision of various common edge cells or dummy cells.

At operation 758, the method 750 conducts syntheses operations, in accordance with some embodiments. In response to identifying the circuit modules (operation 756), the system can match the behavior and/or functions desired from the behavioral/functional design to (standard) cells from one or more cell libraries, and meet the constraints specified by the design constraints and the cell heights specified by the identified circuit modules (the operation 756) to create a functionally equivalent logic gate-level circuit description, such as a netlist (operation 760). In the operation 758, the system can form the netlist by arranging a uniformly tall or short row for each of the circuit modules that have been identified as consisting of either the tall cells or the short cells. Concurrently with arranging the uniformly tall/short rows, the system can arrange one or more areas for each of the circuit modules that have been identified as being constituted by a mix of the tall cells and the short cells, which may include the placement of additional dummy cells to fully define a row, provide redundancy, or otherwise meet one or more DRC. The operation 758 may sometimes be referred to as a “physically aware” synthesis.

In some embodiments, concurrently with generating the netlist, the system can optionally generate a reference floorplan (operation 762). The reference floorplan may include a number of areas that each has been arranged to comprise or abut boundaries. Each of the areas may include corresponding cells placed therein. Such a reference floorplan may function as an initial value or guess for the subsequent operation (e.g., operation 764), which may advantageously reduce calculation (e.g., converge) time.

The remaining operations of the method 750 are substantially similar as the operations discussed with respect to FIG. 7A. For example, operations 764, 766, 768, and 770 are substantially similar to the operations 710, 712, 714, and 716, respectively, according to some embodiments. The discussions of such operations is not repeated here.

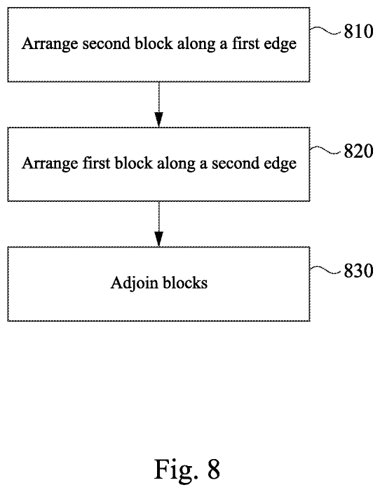

FIG. 8 illustrates a flow chart of an example method 800 of generating an integrated circuit layout including one or more common cell edges and/or one or more dummy cells, in accordance with some embodiments of the present disclosure. In some embodiments, the method 800 may be collectively referred to as an EDA. The illustrated embodiment of the method 800 is merely an example. Therefore, it is understood that any of a variety of operations may be omitted, re-sequenced, and/or added while remaining within the scope of the present disclosure.

At operation 810, a first plurality of cells in a first block are arranged, each of the first cells having a first cell height. For example, the cells may be arranged to abut a boundary. The plurality of cells having the first height may have varied patterns, such as gates, connections, functions, etc. For example, the first plurality of cells may be associated with a plurality of edge cells (e.g., may comprise common edge cells, edge cells of another type).

Operation 810 may comprise arranging a plurality of first edge cells disposed along a first edge of the first block. For example, each of the cells may contain one or more edge cells. The edge cells may be aligned with the boundary. Aligning the edge cells with the edge can include determining a distance between an active region of the cell and the edge. For example a minimum distance to allow a power rail to pass along or join to the edge cell. Aligning the edge cell may comprise, inserting additional cells (such as dummy cells) between the edge and the edge cell to permit the violation of a DRC (e.g., a check against a design rule for a minimum power rail routing zone).

At operation 820, a second plurality of cells in a second block are arranged, each of the second cells having a second height. For example, the cells may be arranged to abut a boundary. The plurality of cells having the second height may have varied patterns, such as gates, connections, functions, etc. For example, the second plurality of cells may be associated with a plurality of edge cells (e.g., may comprise common edge cells, different edge cells of a different type). Operation 820 may comprise arranging a plurality of second edge cells disposed along a second edge of the second block. The arrangement may be similar to the arrangement of operation 810, or be vary therefrom according to the examples and variations presented herein.

At operation 830, the first and second blocks are placed in a row having a spacing that is either equal to zero or less than any of the first or second cell heights. For example, a common edge cell associated with corresponding cells of the first and second plurality of cells may abut each other. In some embodiments, the plurality of the first and second cells may completely define the row. Alternatively or additionally, further cells (e.g., having a third height) may be included in a row. The further cells may be functional or dummy cells. For example, any row height in excess of a height which is less than any of the first or second cell heights may be populated by a first or second cell, which may be redundant with additional cells (e.g., to enable later rerouting operations). Dummy cells may be disposed between the first block and the second block in embodiments in which the spacing is not zero. The dummy cells and the first and second blocks may completely define the row, or additional cells can be included in a row.

Referring now to FIG. 9, a block diagram of an information handling system (IRS) 900 is provided, in accordance with some embodiments. The IHS 900 may be a computer platform used to implement any or all of the processes discussed herein to design an integrated circuit. The IRS 900 may comprise a processing unit 910, such as a desktop computer, a workstation, a laptop computer, or a dedicated unit customized for a particular application. The IHS 900 may be equipped with a display 914 and one or more input/output (I/O) components 912, such as a mouse, a keyboard, or printer. The processing unit 910 may include a central processing unit (CPU) 920, memory 922, a mass storage device 924, a video adapter 926, and an I/O interface 928 connected to a bus 930.

The bus 930 may be one or more of any type of several bus architectures including a memory bus or memory controller, a peripheral bus, or video bus. The CPU 920 may comprise any type of electronic data processor, and the memory 922 may comprise any type of system memory including transitory and non-transitory embodiments thereof, such as static random access memory (SRAM), dynamic random access memory (DRAM), or read-only memory (ROM).

The mass storage device 924 may comprise any type of storage device configured to store data, programs, and other information and to make the data, programs, and other information accessible via the bus 930. The mass storage device 924 may comprise, for example, one or more of a solid state drive, hard disk drive, a magnetic disk drive, an optical disk drive, or the like.

The video adapter 926 and the interface 928 provide interfaces to couple external input and output devices to the processing unit 910. As illustrated in FIG. 9, examples of input and output devices include the display 914 coupled to the video adapter 926 and the I/O components 912, such as a mouse, keyboard, printer, and the like, coupled to the I/O interface 928. Other devices may be coupled to the processing unit 910, and additional or fewer interface cards may be utilized. For example, a serial interface card (not shown) may be used to provide a serial interface for a printer. The processing unit 910 also may include a network interface 940 that may be a wired link to a local area network (LAN) or a wide area network (WAN) 916 and/or a wireless link.

It should be noted that the IHS 900 may include other components/devices. For example, the IHS 900 may include power supplies, cables, a motherboard, removable storage media, cases, and the like. These other components/devices, although not shown, are considered part of the IRS 900.

In some embodiments of the present invention, an EDA is program code that is executed by the CPU 920 to analyze a user file to obtain the layout of an integrated circuit (e.g., the integrated circuit discussed above). Further, during the execution of the EDA, the EDA may analyze functional components of the layout, as is known in the art. The program code may be accessed by the CPU 920 via the bus 930 from the memory 922, mass storage device 924, or the like, or remotely through the network interface 940.

In one aspect of the present disclosure, an integrated circuit layout is disclosed. The integrated circuit layout includes a first block including multiple first cells, each of which has a first cell height, and a second block including multiple second cells, each of which has a second cell height. The first block is disposed next to the second block with a spacing that is either equal to zero or less than any of the first or second cell heights.

In another aspect of the present disclosure, an integrated circuit layout is disclosed. The semiconductor device includes a first block including multiple first cells, each of the first cells having a first cell height and multiple first edge cells disposed along a first edge of the first block, each of the first edge cells having the first cell height. The integrated circuit layout also includes a second block disposed next to the first block and including multiple second cells, each of the second cells having a second cell height greater than the first cell height and a plurality of second edge cells disposed along a second edge of the second block, each of the second edge cells having the first cell height. The first edge and the second edge face each other.

In yet another aspect of the present disclosure, a method for generating an integrated circuit layout is disclosed. The method includes arranging multiple first cells in a first block, each of the first cells having a first cell height, arranging multiple second cells in a second block, each of the second cells having a second cell height, and placing the first block next to the second block with a spacing that is either equal to zero or less than any of the first or second cell height.

As used herein, the terms “about” and “approximately” generally mean plus or minus 10% of the stated value. For example, about 0.5 would include 0.45 and 0.55, about 10 would include 9 to 11, about 1000 would include 900 to 1100.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit layout, comprising:
a first block comprising a plurality of first cells, each of the first cells having a first cell height; and
a second block comprising a plurality of second cells, each of the second cells having a second cell height;
wherein the first block is disposed next to the second block with a spacing that is either equal to zero or less than any of the first or second cell height.

2. The integrated circuit layout of claim 1, wherein the first cell height is equal to the second cell height.

3. The integrated circuit layout of claim 1, wherein the first cell height is different from the second cell height.

4. The integrated circuit layout of claim 1, wherein the first block includes at least a first edge cell disposed along a first edge of the first block and the second block includes at least a second edge cell disposed along a second edge of the second block, and wherein the first edge faces the second edge.

5. The integrated circuit layout of claim 4, wherein the first edge cell and the second edge cell have a common cell height that is equal to a less one of the first cell height and the second cell height.

6. The integrated circuit layout of claim 1, wherein the spacing is equal to p×n, where p is a common factor of the first cell height and the second cell height, and n is a positive integer.

7. The integrated circuit layout of claim 1, further comprising a plurality of first dummy cells and a plurality of second dummy cells interposed between the first block and the second block.

8. The integrated circuit layout of claim 7, wherein the first dummy cells have a first dummy cell height and the second dummy cells have a second dummy cell height greater than the first dummy cell height.

9. The integrated circuit layout of claim 8, wherein the first dummy cell height is equal to a common factor of the first cell height and the second cell height, and the second dummy cell height is equal to a multiple of the common factor.

10. The integrated circuit layout of claim 7, wherein the second dummy cells each have at least one active region, while none of the first dummy cells has an active region.

11. An integrated circuit layout, comprising:
a first block comprising a plurality of first cells, each of the first cells having a first cell height;
a plurality of first edge cells disposed along a first edge of the first block, each of the first edge cells having the first cell height;
a second block disposed next to the first block and comprising a plurality of second cells, each of the second cells having a second cell height greater than the first cell height; and
a plurality of second edge cells disposed along a second edge of the second block, each of the second edge cells having the first cell height;
wherein the first edge and the second edge face each other.

12. The integrated circuit layout of claim 11, wherein a spacing between the first edge and the second edge is equal to zero.

13. The integrated circuit layout of claim 11, wherein a spacing between the first edge and the second edge is less than the first cell height.

14. The integrated circuit layout of claim 11, wherein a spacing between the first edge and the second edge is equal to p×n, where p is a common factor of the first cell height and the second cell height, and n is a positive integer.

15. The integrated circuit layout of claim 11, further comprising a plurality of first dummy cells and a plurality of second dummy cells interposed between the first block and the second block.

16. The integrated circuit layout of claim 15, wherein the first dummy cells have a first dummy cell height and the second dummy cells have a second dummy cell height greater than the first dummy cell height.

17. The integrated circuit layout of claim 16, wherein the first dummy cell height is equal to a common factor of the first cell height and the second cell height, and the second dummy cell height is equal to a multiple of the common factor.

18. The integrated circuit layout of claim 15, wherein the second dummy cells each have at least one active region, while none of the first dummy cells has an active region.

19. A method for generating an integrated circuit layout, comprising:
arranging a plurality of first cells in a first block, each of the first cells having a first cell height;
arranging a plurality of second cells in a second block, each of the second cells having a second cell height; and
placing the first block next to the second block with a spacing that is either equal to zero or less than any of the first or second cell height.

20. The method of claim 19, further comprising:
arranging a plurality of first edge cells disposed along a first edge of the first block; and
arranging a plurality of second edge cells disposed along a second edge of the second block;
wherein the first edge cells and the second edge cells have a common cell height that is equal to a less one of the first cell height and the second cell height.
